(19) United States
(12) Patent Application Publication
(10) Pub. No.: US 2005/0189555 A1
(43) Pub. Date: Sep. 1, 2005

(54) Light-emitting device having light-reflecting layer on power substrate

(76) Inventors: Ming-Der Lin, Hsinchu (TW); San-Bao Lin, Jungli City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/063,774

(22) Filed: Feb. 24, 2005

(30) Foreign Application Priority Data
Feb. 27, 2004 (TW) 093105195

(51) Int. Cl. H01L 33/00

(52) U.S. Cl. 257/98; 257/99; 257/100

(57) ABSTRACT

A light-emitting device is provided, having a light-reflecting layer on a power substrate, the main structure of which comprises a power substrate, at least one light-emitting die fixedly provided on a top surface of the power substrate, a light-reflecting body surroundingly provided around the periphery of the power substrate and light-emitting die, and a supporting foundation. At a side surface of the power substrate, there is coated with at least one light-reflecting layer, by which a side light source generated from the light-emitting die may be reflected out of the light-emitting device, free from being absorbed by the power substrate, thus raising the brightness of the light-emitting device.

### FIELD OF THE INVENTION

The present invention is related to a light-emitting device, particularly to a light-emitting device having a light-reflecting layer on a power substrate which is coated at a side surface thereof with at least one light-reflecting layer in cooperation with an appropriately arranged light-reflecting body, thus raising the brightness of the light-emitting device.

### BACKGROUND

Light-emitting diodes (LEDs) have been widely used in computer peripherals, communication products, and other electronic apparatus owing to advantages, such as small volume, light weight, lower power consumption, and long service life, as examples. How to raise the brightness of various LEDs in the design process thereof is exactly the object intended to achieve by the industry with considerable expenditure and elaborate research.

Referring to FIG. 1, there is shown a diagram of a package structure of a conventional LED device. As illustrated in this figure, a LED device 10 mainly comprises a power substrate 13 fixedly provided on a top surface of a supporting foundation 11, and a light-emitting die 15 fixedly provided on a top surface of the power substrate 13. Moreover, on the top surface of the supporting foundation 11, there is provided a light-reflecting body 111 around the periphery of the light-emitting die 15 and power substrate 13.

The light-reflecting body 111 includes a first light-reflecting incline 113, by which a beam 191, having an upward deviating projection direction, of a side light source projected from the light-emitting die 15 is reflected up the LED device 10. However, beams 193, 195, having downward deviating projection directions, of the side light source are projected toward and then absorbed by the power substrate 13 after they are reflected by the first light-reflecting incline 113, causing the imperfection of significant reduction in the brightness of the LED device 10. Additionally, the non-uniform spatial distribution of the projection light source, and thus a dark region formed on a lighted target may occur easily, when the beams 193, 195 are absorbed by the power substrate.

For this purpose, another LED device 20 having a light-reflecting body 211 with two slopes, as shown in FIG. 2, is proposed by the industry. With a first light-reflecting incline 213, which is disposed at the upper half part of the light-reflecting body 211 and having a steeper slope, the beam 191 with upward deviating projection direction of the side light source projected from the light-emitting die 15 is reflected up the LED device 10. Whereas, a beam 293 with downward deviating projection direction may be guided, under the reflective effect of a second light-reflecting incline 215 located at the lower part of the light-reflecting body 211 with a relatively smaller slope, so as to project up the LED device 20. However, it is still unavoidable for a beam 295 projecting downwardly at a larger inclination angle to be absorbed by the power substrate 13. Thus, although the relatively enhanced brightness of the LED device is achieved, there may be a lot of room for improvement on this enhancement.

### SUMMARY OF THE INVENTION

For this purpose, how to design a novel light-emitting diode (LED) device with not only enhanced brightness but also lowered energy consumption, aiming at the disadvantages of the above conventional art, is the key point of the present invention.

Accordingly, it is the primary object of the present invention to provide a light-emitting device having a light-reflecting layer on a power substrate, the power substrate being coated at a side surface thereof with at least one light-reflecting layer in cooperation with a light-reflecting body disposed around the periphery of the light-emitting die and power substrate, such that a side light source projected from the light-emitting die is guided to project outside, further raising brightness of the light-emitting device.

It is the secondary object of the present invention to provide a light-emitting device having a light-reflecting layer on a power substrate, allowed to achieve the object of saving energy and lowering power consumption by means of a suitable design for light guidance.

It is another object of the present invention to provide a light-emitting device having a light-reflecting layer on a power substrate, capable of preventing a side light source from being absorbed by the power substrate, resulting in avoiding the thus generated non-uniform spatial distribution of the projection light source and a resultant dark region formed on a lighted target.

For the purpose of achieving aforementioned objects, the present invention provides a light-emitting device having a light-reflecting layer on a power substrate, the main structure thereof comprising: a supporting foundation defined with a first location and a second location on a top surface thereof; a power substrate fixedly provided at the first location of the supporting foundation and coated at a side surface thereof with at least one light-reflecting layer; at least one light-emitting die fixedly provided on a top surface of the power substrate; and a light-reflective body fixedly provided on the top surface of the supporting foundation and surroundingly provided around the periphery of the light-emitting die and power substrate, served for changing the projection direction of a side light source generated from the light-emitting die.

### BRIEF DESCRIPTION OF DRAWINGS

FIG. 1 is a structural diagram of a conventional light-emitting device;

FIG. 2 is a structural diagram of another conventional light-emitting device; and

FIG. 3 is a structural side view according to one preferred embodiment of the present invention.

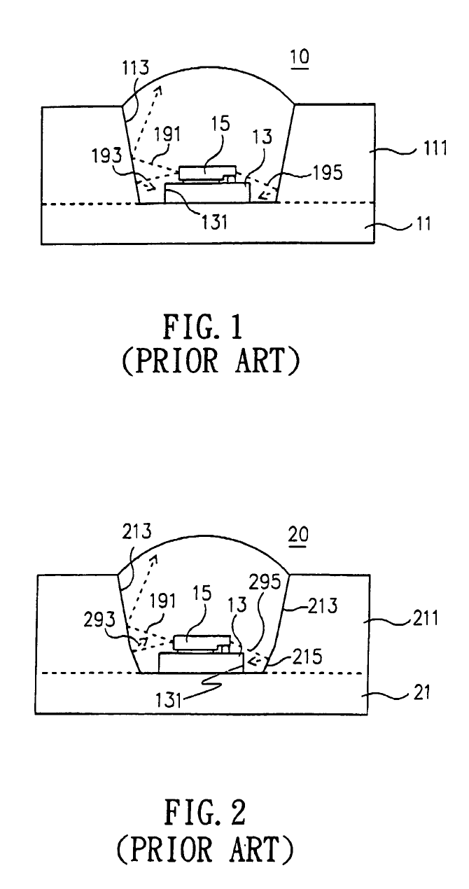

### DETAILED DESCRIPTION

The structural features and the effects to be achieved may further be understood and appreciated by reference to the presently preferred embodiments together with the detailed description.

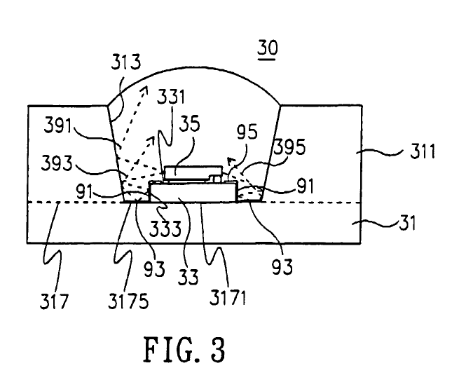

Referring to FIG. 3, there is shown a structural diagram of a light-emitting device according to one preferred embodiment of the present invention. As illustrated in this figure, a light-emitting device 30 of the present invention mainly comprises a light-emitting die 35 fixedly provided at a predetermined location on a top plane 331 of a power substrate 33, which is then fixedly provided at a first location 3171 on a top plane of foundation 317 of a supporting foundation 31. Around the periphery of the light-emitting die 35 and power substrate 33, there is fixedly provided with a light-reflective body 311 on the top plane of foundation 317, while along a side surface 333 of the power substrate 33, there is coated with a light-reflecting layer 91. Also, a light-reflecting layer of foundation 93 is provided at a second location 3175, between the power substrate 33 and the light-reflective body 311, on the top plane of foundation 317. In addition, on a part of the top plane 331 of the power substrate 33, there may be also provided with an upper light-reflecting layer 95 in order to enhance the light-reflective effect.

In this case, the power substrate 33 may be selectively made from Si, AlN, BeO, SiC, Al₂O₃, glass, quartz, sapphire, or other materials, based on the principle in which the material having a high coefficient of thermal conductivity and a coefficient of thermal expansion approaching to that of the light-emitting die 35 is preferable. Naturally, the power substrate 33 may be also served as an electrostatic discharge protection device. The electrostatic discharge protection device, composed of a plurality of zener diodes, Schottky barrier diodes, and electrostatic discharge protection integrated circuits, for instance, may be used for this power substrate, in such a way that the prevention of electrostatic damage is provided in the present invention.

Further, it is similar to the conventional art that, when the light-emitting die 35 projects a side light source, a beam 391 projected therefrom with upward deviating projection direction is projected upwardly under the light-reflective effect of a first light-reflecting incline 313 directly. Whereas, for beams 393, 395 with downward deviating projection direction, reflecting back and forth among the light-reflecting layer 91, the light-reflecting layer of foundation 93, and the first light-reflecting incline 313 may be possible, in order for changing their projection directions, and finally projecting them out of the light-emitting device 30 from the top equally. As such, the absorption provided by the power substrate (13) and then the reduction in overall brightness, as the conventional structure illustrated in FIG. 1, may not exist.

Through repeated experiments, it could be found that the brightness of the light-emitting device 30 provided with the light-reflecting layer 91 and the light-reflecting layer of foundation 93 is significantly enhanced by over ten percent with respect to that of the conventional light-emitting diode (LED) device (10) in the same condition. Indeed, the function of the enhancement of brightness may be affected, further achieving the object of saving power. Moreover, the non-uniform spatial distribution of the projection light source, and thus the formation of a dark region on a lighted target may not occur as well, due to the fact that the beams 393, 395 may be projected outside without being absorbed by the power substrate 33.

In this situation, the light-emitting die 35 is not limited to a flat LED having two electrodes located at the same side, but also allowed to apply to an upright LED having two electrodes located at different sides. For the flat LED, the effect of enhancing the brightness may be further raised, if a flip-chip package is utilized. Additionally, the supporting foundation 31 and the light-reflecting body 311 may be fabricated separately and then assembled together. Of course, the integral design is also possible.

Moreover, these light-reflecting layer 91 and light-reflecting layer of foundation 93 may be selectively composed of metal materials, insulating materials, or other chemical materials. The metal material, such as Au, Ag, Cu, Al, Be, Cr, Pd, Ni, and so on, is suitable, while the insulating material, such as SiNₓ, SiO₂, Al₂O₃, TiO₂, and other chemical materials, is applicable. Additionally, the light-reflecting layer 91 and the light-reflecting layer of foundation 93 are not limited to a single layer film structure, but a multilayer film structure is also possibly used in order to enhance the reflective effect thereof.

To sum up, it should be understood that the present invention is related to a light-emitting device, particularly to a light-emitting device having a light-reflecting layer on a power substrate which is coated at a side surface thereof with at least one light-reflecting layer in cooperation with an appropriately arranged light-reflecting body, thus raising the brightness of the light-emitting device.

The foregoing description is merely one embodiment of present invention and not considered as restrictive. All equivalent variations and modifications in process, method, feature, and spirit in accordance with the appended claims may be made without in any way from the scope of the invention.

### LIST OF REFERENCE SYMBOLS

10 light-emitting diode device
11 supporting foundation
111 light-reflecting body
113 first light-reflecting incline
13 power substrate
131 side surface
15 light-emitting die
191 beam
193 beam
195 beam
20 light-emitting diode device
211 light-reflecting body
213 first light-reflecting incline
215 second light-reflecting incline
293 beam
295 beam
30 light-emitting device
31 supporting foundation
311 light-reflecting body
313 first light-reflecting incline
317 top plane of foundation
3171 first location
3175 second location
33 power substrate
331 top plane
333 side surface
35 light-emitting die
391 beam
393 beam
395 beam
91 light-reflecting layer
93 light-reflecting layer of foundation
95 upper light-reflecting layer

1. A light-emitting device having a light-reflecting layer on a power substrate, comprising:
a supporting foundation defined with a first location and a second location on a top surface thereof;
a power substrate fixedly provided at said first location of said supporting foundation and coated at a side surface thereof with at least one light-reflecting layer;
at least one light-emitting die fixedly provided on a top surface of said power substrate; and
a light-reflective body fixedly provided on said top surface of said supporting foundation and surroundingly provided around the periphery of said light-emitting die and power substrate, served for changing the projection direction of a side light source generated from said light-emitting die.

2. The light-emitting device according to claim 1, wherein a part of said top surface of said power substrate is also coated with an upper light-reflecting layer.

3. The light-emitting device according to claim 1, wherein a light-reflecting layer of foundation is also provided at said second location on said top surface of said supporting foundation.

4. The light-emitting device according to claim 1, wherein said light-reflective body and said foundation are formed integrally.

5. The light-emitting device according to claim 1, wherein said light-emitting die is selected from one of a flat light-emitting die and an upright light-emitting die.

6. The light-emitting device according to claim 5, wherein said flat light-emitting die is fixedly provided on said power substrate in a manner of flip-chip.

7. The light-emitting device according to claim 1, wherein said light-reflecting layer is presented as that selected from one of a single layer film structure and a multilayer film structure.

8. The light-emitting device according to claim 1, wherein said light-reflecting layer is composed of that selected from the group consisting of a metal material, insulating material, and the combination thereof.

9. The light-emitting device according to claim 8, wherein said metal material is composed of a material selected from the group consisting of Au, Ag, Cu, Al, Be, Cr, Pd, Ni, and the combination thereof.

10. The light-emitting device according to claim 8, wherein said insulating material is composed of a material selected from the group consisting of SiNₓ, SiO₂, Al₂O₃, TiO₂, and the combination thereof.

11. The light-emitting device according to claim 1, wherein said power substrate is composed of a material selected from the group consisting of Si, AlN, BeO, SiC, Al₂O₃, glass, quartz, sapphire, and the combination thereof.

12. The light-emitting device according to claim 1, wherein said power substrate is allowed to be an electrostatic discharge protection device.

13. A light-emitting device having a light-reflecting layer on a power substrate, the main structure thereof comprising:
a power substrate coated at a side surface thereof with at least one light-reflecting layer; and
at least one light-emitting die fixedly provided on a top surface of said power substrate.

14. The light-emitting device according to claim 13, wherein a part of said top surface of said power substrate is also coated with an upper light-reflecting layer.

15. The light-emitting device according to claim 13, wherein said light-emitting die is selected from one of a flat light-emitting die and an upright light-emitting die.

16. The light-emitting device according to claim 13, wherein said light-reflecting layer is composed of that selected from the group consisting of a metal material, insulating material, and the combination thereof.

17. The light-emitting device according to claim 13, wherein said power substrate is composed of a material selected from the group consisting of Si, AlN, BeO, SiC, Al₂O₃, glass, quartz, sapphire, and the combination thereof.
